(19) United States
(12) Patent Application Publication
(10) Pub. No.: US 2002/0176466 A1
(43) Pub. Date: Nov. 28, 2002

(54) Semiconductor laser device, semiconductor laser module, and raman amplifier using the device or module

(76) Inventor: Young Duk Yoon, Tokyo (JP)

Correspondence Address: COUDERT BROTHERS LLP, 3rd Floor, 600 Beach Street, San Francisco, CA, 94109, US

(21) Appl. No.: 10/116,578

(22) Filed: Apr. 3, 2002

(30) Foreign Application Priority Data
May 11, 2001 (JP) 2001-142306

(51) Int. Cl. H01S 5/00

(52) U.S. Cl. 372/49

(57) ABSTRACT

In a semiconductor laser device, a transmission film having a low reflectivity is provided on a laser beam radiation end surface side of a laser element having an active layer therein, and a dielectric multilayer film having a reflection wavelength bandwidth set to be not larger than 10 nm is provided on a laser beam reflection end surface side as a laser beam reflection film. As a result, the laser beam oscillated from the laser element is wavelength-selected by the laser beam reflection film and is emitted from the transmission film.

### FIELD OF THE INVENTION

The present invention relates to a semiconductor laser device and a semiconductor laser module and a Raman amplifier using the semiconductor laser device or the semiconductor laser module.

### BACKGROUND OF THE INVENTION

Recently, with popularization of various multimedia such as Internet, a demand to increase the capacity of the optical communication is increasing. Conventionally, in the optical communication, it is common to transmit information by a single wavelength in a band of 1310 nm or 1550 nm, which has small light absorption by an optical fiber. With this method, it is necessary to increase the number of cores of optical fibers to be disposed in a transmission path, in order to transmit a large quantity of information, thereby causing a problem in that the cost increases, with an increase in the transmission capacity.

Therefore, a wavelength division multiplexing (WDM) communication method is now being used. In this WDM communication method, an erbium doped fiber amplifier (EDFA) is mainly used, to transmit information using a plurality of wavelengths in the 1550 nm band, which is the operation band thereof. With this WDM communication method, since one optical fiber is used to transmit optical signals of a plurality of different wavelengths simultaneously, it is not necessary to lay a new line, making it possible to remarkably increase the transmission capacity of the network.

A common WDM communication method using this EDFA has been put into practical use from 1550 nm, where flattening of gain is easy, and recently, the band has been expanded to 1580 nm, which has not been used due to a small gain coefficient. However, since a low loss band of the optical fiber is wider than a band that can be amplified by the EDFA, the spotlight has been centered on an optical amplifier operated in the band outside the EDFA band, that is, the Raman amplifier.

While a gain wavelength range of an optical amplifier using rare earth ions such as erbium as a medium is determined by an energy level of the ion, the Raman amplifier has a characteristic that the gain wavelength range is determined by a wavelength of an exciting light, and an optional wavelength range can be amplified by selecting the exciting light wavelength.

With the Raman amplification, when a strong exciting light is incident onto the optical fiber, a gain appears on the long wavelength side by about 100 nm from the exciting light wavelength, due to induced Raman scattering. When a signal light in the wavelength band having this gain is incident onto the optical fiber in this excited state, this signal light is amplified. Therefore, with the WDM communication method using the Raman amplifier, the number of channels of the signal light can be further increased, as compared with the communication method using the EDFA.

FIG. 10 is a block diagram which shows the structure of a conventional Raman amplifier used in the WDM communication system. In FIG. 10, semiconductor laser modules 182a to 182d which include Fabry-Perot type semiconductor light emission elements 180a to 180d and fiber gratings 181a to 181d respectively in pair, output laser beams, which are the exciting light source, to polarization synthesizing couplers 61a and 61b. The wavelengths of laser beams output from the respective semiconductor laser modules 182a and 182b are the same, but lights having different planes of polarization are synthesized by the polarization synthesizing coupler 61a. Similarly, the wavelengths of the laser beams output from the respective semiconductor laser modules 182c and 182d are the same, but lights having different planes of polarization are synthesized by the polarization synthesizing coupler 61b. The polarization synthesizing couplers 61a and 61b output the polarization-synthesized laser beams respectively to a WDM coupler 62. The wavelengths of laser beams output from the polarization synthesizing couplers 61a and 61b are different from each other.

The WDM coupler 62 couples the laser beam output from the polarization synthesizing couplers 61a and 61b, and outputs it to an amplification fiber 64 as the exciting light, through a WDM coupler 65. A signal light to be amplified is input from a signal light input fiber 69 through an isolator 63 to the amplification fiber 64 to which the exciting light has been input, and coupled with the exciting light and is Raman-amplified.

The signal light (amplified signal light) Raman-amplified in the amplification fiber 64 is input to a monitor light distribution coupler 67 through the WDM coupler 65 and an isolator 66. The monitor light distribution coupler 67 outputs a part of the amplified signal light to a control circuit 68, and outputs the remaining amplified signal light to a signal light output fiber 70 as the output laser beam.

The control circuit 68 controls the light emitting state, for example, optical intensity of each of the semiconductor light emission elements 180a to 180d based on the input part of the amplified signal light, and feedback controls so that the gain band of the Raman amplification has a flat characteristic.

FIG. 11 is a diagram which shows a schematic structure of a semiconductor laser module using the fiber grating. In FIG. 11, the semiconductor laser module 201 has a semiconductor light emission element 202 and an optical fiber 203. The semiconductor light emission element 202 has an active layer 221. The active layer 221 is provided with a light reflection surface 222 at one end, and a light radiation surface 223 at the other end. The light generated in the active layer 221 is reflected by the light reflection surface 222 and is output from the light radiation surface 223.

The optical fiber 203 is arranged on the light radiation surface 223 of the semiconductor light emission element 202, and optically coupled with the light radiation surface 223. In a core 232 of the optical fiber 203, a fiber grating 233 is formed at a predetermined position from the light radiation surface 223, and the fiber grating 233 selectively reflects light of the characteristic wavelength. That is, the fiber grating 233 functions as an external resonator, and forms a resonator between the fiber grating 233 and the light reflection surface 222, and the laser beam of a specific wavelength selected by the fiber grating 233 is amplified and output as an output laser beam 241.

In the above-described semiconductor laser module 201, adjustment of the reflectivity of the light radiation surface 223 of the semiconductor light emission element 202 and the reflectivity of the fiber grating 233, and adjustment so as to coincide the oscillation wavelength of the semiconductor light emission element 202 with the center wavelength selected by the fiber grating 233 are required. However, it is difficult to accurately perform adjustment of the respective reflectivity or adjustment so that the wavelengths are made to coincide with each other, due to differences between manufactured individual semiconductor light emission elements 202, or differences between manufactured individual fiber gratings 233. Further, taking an individual combination of the semiconductor light emission element 202 and the fiber grating 233 into consideration, it is difficult to easily and stably realize a semiconductor laser device having wavelength selectivity in a narrow band.

In the semiconductor laser module 201 (182a to 182d), since a distance between the fiber grating 233 and the semiconductor light emission element 202 is long, a relative intensity noise (RIN) increases due to resonance between the fiber grating 233 and the light reflection surface 222. With the Raman amplification, since the process in which amplification occurs comes early, when the exciting light intensity is fluctuated, the Raman gain also fluctuates. This fluctuation of the Raman gain is output directly as the fluctuation of the amplified signal intensity, causing a problem in that stable Raman amplification cannot be performed.

As the Raman amplifier, there are a rear-side excitation method in which a signal light is excited from the rear side, like the Raman amplifier shown in FIG. 10, as well as a front-side excitation method in which a signal light is excited from the front side, and a bi-directional excitation method in which a signal light is excited bi-directionally. The one mainly used as the Raman amplifier at present is the rear-side excitation method. The reason is that the front-side excitation method in which the weak signal light progresses in the same direction together with the strong exciting light has a problem in that the excited optical intensity fluctuates. Therefore, it is desired to develop a stable excitation light source also applicable to the front-side excitation method. That is to say, when a semiconductor laser module using the conventional fiber grating is used, there is a problem in that the applicable excitation method is limited.

The Raman amplification in the Raman amplifier is based on a condition that a polarization direction of the signal light coincides with a polarization direction of the exciting light. That is to say, the Raman amplification has a polarization dependency of the amplified gain, and it is necessary to reduce an influence caused by a deviation between the polarization direction of the signal light and the polarization direction of the exciting light. According to the rear-side excitation method, the signal light has no problem since the polarization becomes random during propagation. According to the front-side excitation method, however, the polarization dependency is strong, and it is necessary to reduce the polarization dependency by means of cross polarization synthesis, depolarization or the like of the exciting light. That is, it is necessary to reduce the degree of polarization (DOP).

Further, with the Raman amplification, since the obtained amplification rate is relatively low, an excitation light source for Raman amplification with a high output is desired.

### SUMMARY OF THE INVENTION

It is an object of this invention to provide a semiconductor laser device and a semiconductor laser module suitable for an excitation light source for Raman amplifiers, which can output a laser beam in a narrow band stably with a simple construction, and particularly, which can obtain a high gain.

According to one aspect of the invention, there is provided a semiconductor laser device in which an optical resonator is formed by providing a transmission film having a low reflectivity on a laser beam radiation end surface side of a laser element having an active layer therein, and a reflection film having a high reflectivity on a laser beam reflection end surface side, and the reflection film is formed by a dielectric multilayer film having a reflection wavelength bandwidth set to be not larger than 10 nm.

According to the above aspect, the semiconductor laser device comprises the dielectric multilayer film having a reflection wavelength bandwidth of not larger than 10 nm, on the laser beam reflection end surface of the laser element having the active layer therein, to thereby reflect the light generated in the active layer.

According to another aspect of the present invention, there is provided a semiconductor laser device comprising a laser element body provided with a transmission film having a low reflectivity on a laser beam radiation end surface side of a laser element having an active layer therein, and a reflection film which is physically independent of the laser element body, and is formed by a high-reflectivity dielectric multilayer film having a reflection wavelength bandwidth set to be not larger than 10 nm, to function as a reflection end surface of an optical resonator, wherein an optical resonator is formed such that the active layer is interposed between the transmission film and the reflection film.

According to the above aspect, in the semiconductor laser device, the laser element provided with the transmission film on the radiation side end surface is combined with the dielectric multilayer film having the reflection wavelength bandwidth of not larger than 10 nm, to thereby form the resonator.

According to still another aspect of the invention, there is provided a semiconductor laser module comprising: the semiconductor laser device explained above; an optical fiber which wave-guides the laser beam emitted from the semiconductor laser device to the outside; an optical coupling lens system which optically couples the semiconductor laser device and the optical fiber; a temperature control unit which controls the temperature of the semiconductor laser device; and an isolator arranged in the optical coupling lens system, to control the incidence of a reflected return light from the optical fiber side.

According to the above aspect, since a semiconductor laser device which does not use a fiber grating is used, a large isolator can be used, different from the in-line type fiber, thereby enabling realization of a semiconductor laser module having a small insertion loss.

According to still another aspect of the invention, there is provided a Raman amplifier which uses the semiconductor laser device or the semiconductor laser module explained above as an excitation light source for broadband Raman amplification.

According to the above aspect, the semiconductor laser device or the semiconductor laser module explained above is used as an excitation light source for broadband Raman amplification, so that the operation effects of each of the semiconductor laser devices or each of the semiconductor laser modules can be exerted.

Other objects and features of this invention will become understood from the following description with reference to the accompanying drawings.

### BRIEF DESCRIPTION OF THE DRAWING

FIG. 1 is a perspective view which shows the schematic structure of a semiconductor laser device, which is a first embodiment of this invention,

FIG. 2 is a diagram which explains the wavelength selectivity of a reflection film shown in FIG. 1,

FIGS. 3A and 3B are diagrams which show the relationship of a laser beam output power between a single oscillation longitudinal mode and a plurality of oscillation longitudinal modes, and a threshold value of induced Brillouin scattering,

FIG. 4 is a perspective view which shows the schematic structure of a semiconductor laser device, which is a second embodiment of this invention,

FIG. 5 is a diagram which explains the production procedure of the semiconductor laser device shown in FIG. 4,

FIG. 6 is a perspective view which shows an instance when a laser element and a reflection film are bonded by a light permeable resin,

FIG. 7 is a sectional view which shows an instance of a semiconductor laser device when a lens is provided between the laser element and the reflection film,

FIG. 8 is a longitudinal sectional view which shows the structure of a semiconductor laser module, which is a third embodiment of this invention;

FIG. 9 is a block diagram which shows the structure of a Raman amplifier, being a fourth embodiment of this invention;

FIG. 10 is a block diagram which shows the structure of a conventional Raman amplifier, and

FIG. 11 is a diagram which shows the schematic structure of a semiconductor laser module using a fiber grating.

### DETAILED DESCRIPTIONS

The preferred embodiments of the semiconductor laser device and the semiconductor laser module according to this invention will now be explained, with reference to the accompanying drawings.

(First Embodiment)

A first embodiment of the present invention will be explained. FIG. 1 is a perspective view which shows the schematic structure of a semiconductor laser device, which is a first embodiment of this invention. The semiconductor laser device 1 has a laser element 2, a transmission film 3 and a reflection film 4. The laser element 2 has an active layer (not shown) therein, and emits light when a driving current is supplied. The transmission film 3 having a reflectivity of not larger than 5% is formed on one end surface of the laser element 2 in the longitudinal direction. The reflection film 4 is formed on the other end surface of the laser element 2. The transmission film 3 and the reflection film 4 form an optical resonator. Light generated inside the laser element 2 propagates reciprocally in this optical resonator, amplified by induced emission, and is emitted from the transmission film 3 as a laser beam.

The reflection film 4 is a dielectric multilayer film formed on an end surface of the laser element 2, by forming an SiO₂ film and an Si film alternately so as to repeatedly form a high refractive index film and a low refractive index film. By forming the SiO₂ film and the Si film alternately, the reflection film 4 has the wavelength selection characteristic. Number of layers of this dielectric multilayer film is 20 layers or less, and optical film thickness is not larger than 30μ per one layer. The optical film thickness is a value obtained by multiplying the refractive index by the film thickness.

The SiO₂ film and the Si film are formed using the CVD. For example, when the number of layers of the dielectric multilayer film is 9, an SiO₂ film having a thickness of 33 nm and a refractive index of “1.4619” is formed as the first layer. Then, an Si film having a thickness of 8936 nm and a refractive index of “3.3649” is formed as the second layer. An SiO₂ film having a thickness of 20551 nm and a refractive index of “1.4619” is formed as the third layer. An Si film having a thickness of 8885 nm and a refractive index of “3.3649” is formed as the fourth layer. An SiO₂ film having a thickness of 20509 nm and a refractive index of “1.4619” is formed as the fifth layer. An Si film having a thickness of 8918 nm and a refractive index of “3.3649” is formed as the sixth layer. An SiO₂ film having a thickness of 20484 nm and a refractive index of “1.4619” is formed as the seventh layer. An Si film having a thickness of 8906 nm and a refractive index of “3.3649” is formed as the eighth layer. Then, an SiO₂ film having a thickness of 260 nm and a refractive index of “1.4619” is formed as the ninth layer.

For the CVD device, an ICP-CVD device or the like can be used. The ICP-CVD device generates a plasma of a reactive gas by applying a high frequency voltage to a coil, to form a thin film by plasma discharge disassembly. By using this ICP-CVD, a film having a thickness of from 200 to 300 nm can be formed in one minute, and hence the SiO₂ film and the Si film can be formed at a high speed.

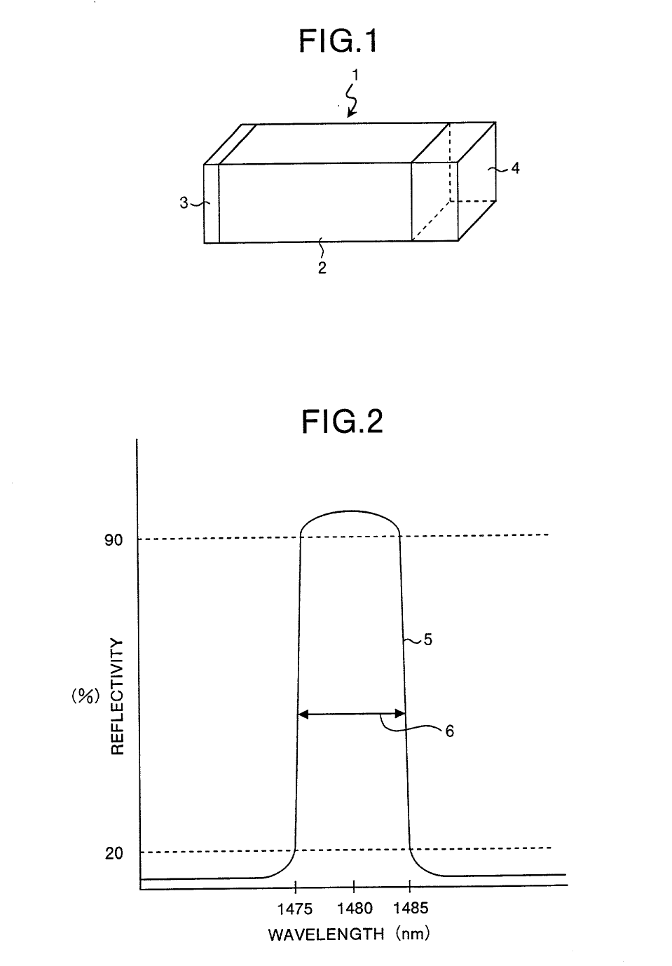

The wavelength selection characteristic by this reflection film 4 makes the reflectivity distribution 5 shown in FIG. 2. The reflectivity distribution 5 has a reflectivity of not smaller than 90% within the reflection wavelength bandwidth 6, and a reflectivity of not larger than 20% outside the reflection wavelength bandwidth 6. It is desirable that the reflectivity in the reflection wavelength bandwidth 6 is not smaller than 95% and the reflectivity outside the reflection wavelength bandwidth 6 is not larger than 10%.

The reflection wavelength bandwidth 6 is set to be not larger than 10 nm. The reflection wavelength bandwidth 6 shown in FIG. 2 has a center wavelength of 1480 nm and a width of 10 nm. Thereby, light having a wavelength within the reflection wavelength bandwidth 6, that is light having a wavelength of from 1475 nm to 1480 nm, is reflected by 90% or more. Light having a wavelength outside the reflection wavelength bandwidth 6 is reflected by 20% or less. When a conventional reflection film 4 is formed by a dielectric multilayer film, the reflection wavelength bandwidth 6 is for example 600 nm, and the order of the reflection wavelength bandwidth 6 is totally different. The dielectric multilayer film which is the reflection film 4 shown in this first embodiment realizes a narrow-band wavelength selectivity by increasing the number of layers as explained above.

It is a presupposition that the semiconductor laser device 1 according to the first embodiment is used as the excitation light source for a Raman amplifier, and the oscillation wavelength λ₀ thereof is from 1300 nm to 1550 nm, and the resonator length L is designated as 800 μm or longer. In general, the mode distance Δλ of the longitudinal mode generated by the resonator of the semiconductor laser device can be expressed by the following expression, assuming that the equivalent refractive index is “n”. That is,

Δλ=λ₀²/(2·n·L).

Here, if the oscillation wavelength λ₀ is designated as 1480 μm, and the equivalent refractive index is designated as 3.5, when the resonator length is 800 μm, the mode distance Δλ of the longitudinal mode becomes about 0.39 nm. As the resonator length increases, the mode distance of the longitudinal mode becomes narrower, and the selection condition to emit a laser beam of a single longitudinal mode becomes stricter.

In this first embodiment, a plurality of oscillation longitudinal modes is made to exist within the reflection wavelength bandwidth 6. In a conventional semiconductor laser device, when the resonator length L is designated as 800 μm or longer, single longitudinal mode oscillation is difficult, and hence a semiconductor laser device having such a resonator length L has not been used. However, in the semiconductor laser device 1 according to the first embodiment, by positively making the resonator length L 800 μm or longer, and using the wavelength selectivity of the reflection film 4 which has a center wavelength of 1480 μm and a reflection wavelength bandwidth 6 of 10 nm, a laser beam having a plurality of oscillation longitudinal modes is made to be output.

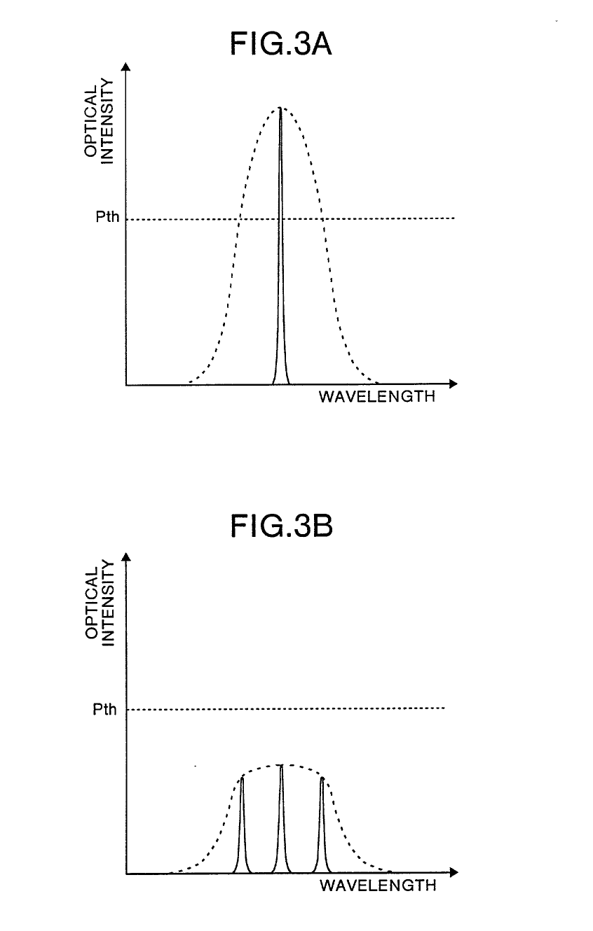

When a laser beam having a plurality of oscillation longitudinal modes is used, high laser output value can be obtained, while suppressing the peak value of the laser output, as compared with when a laser beam having a single longitudinal mode is used. For example, the semiconductor laser device shown in the first embodiment has a profile shown in FIG. 3 (b), wherein an optical laser output can be obtained with a low peak value. On the other hand, FIG. 3(a) shows a profile of a semiconductor laser device having a single longitudinal mode oscillation, when the same laser output is to be obtained, and it has a high peak value.

When the semiconductor laser device is used as an excitation light source for a Raman amplifier, it is preferable to increase the output power of the exciting light in order to increase the Raman gain. However, if the peak value thereof is high, there is a problem in that induced Brillouin scattering occurs to thereby increase noise. The occurrence of the induced Brillouin scattering has a threshold value Pth at which the induced Brillouin scattering occurs. When the same laser output power is to be obtained, as shown in FIG. 3 (b), by having a plurality of oscillation longitudinal modes to suppress the peak value, a high output power of the exciting light can be obtained within the threshold value Pth of the induced Brillouin scattering. As a result, a high Raman gain can be obtained.

The wavelength distance (mode distance) Δλ between the oscillation longitudinal modes is made to be 0.1 nm or larger. This is because when the semiconductor laser device 1 is used as the excitation light source for the Raman amplifier, when the mode distance Δλ is not larger than 0.1 nm, there is a high possibility that the induced Brillouin scattering may occur.

On the other hand, the number of oscillation longitudinal modes included in the reflection wavelength bandwidth is preferably three or more. This is because, when the semiconductor laser device 1 is used as the excitation light source for the Raman amplifier, since there is a polarization dependency such that the Raman amplification occurs in a state that the polarization direction of a signal light coincides with the polarization direction of an exciting light, it is necessary to use a polarization maintaining fiber to polarization-synthesize the exciting light output from the semiconductor laser device 1 so that the exciting light does not include a polarized light. Generally, as the number of oscillation longitudinal modes increases, the necessary length of the polarization maintaining fiber can be made short. In particular, when the number of oscillation longitudinal modes is four or five, the necessary length of the polarization maintaining fiber is made extremely short. Therefore, by setting the number of oscillation longitudinal modes to three or more, and particularly, four or more, the length of the polarization maintaining fiber used for the Raman amplifier can be made short, thereby the Raman amplifier can be further simplified and reduced in size. Further, as the number of oscillation longitudinal modes increases, the coherent length becomes short, and the degree of polarization (DOP) is reduced due to depolarization, thereby enabling elimination of the polarization dependency. As a result, the Raman amplifier can be further simplified and reduced in size.

Here, when the width of the oscillation wavelength spectrum is too wide, coupling loss due to the wavelength synthesizing coupler increases, thereby causing noise or gain variation depending on the movement of the wavelength in the width of the oscillation wavelength spectrum. Hence, it is necessary that the width of the reflection wavelength range is not larger than 10 nm.

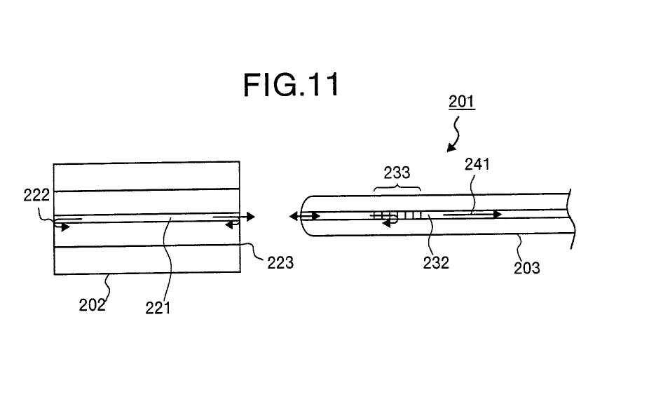

With the conventional semiconductor laser device, as shown in FIG. 11, a semiconductor laser module is formed using a fiber grating, and hence the relative intensity noise (RIN) increases due to a resonance between the fiber grating 233 and the light reflection surface 222, and as a result, stable Raman amplification cannot be performed. However, the semiconductor laser device 1 shown it the first embodiment does not use the fiber grating 233, and the laser beam emitted from the reflection film 4 is directly used as the excitation light source for the Raman amplifier. Hence, the relative intensity noise decreases, and as a result, fluctuations in the Raman gain decrease, thereby enabling stable Raman amplification.

In the semiconductor laser module shown in FIG. 11, there are problems in that a weak laser beam amplified by a resonator structure formed by the light reflection surface 222 and the light radiation surface 223 of the semiconductor light emission element 202 is output, which affects a laser beam selected by the light reflection surface 222 and the fiber grating 233, and causes a kink on the injection current-optical output characteristic, thereby making the optical output unstable. In this semiconductor laser device 1 according to the first embodiment, however, since it does not use the fiber grating 233, stable optical output can be obtained. As a result, when used as the excitation light source for the Raman amplifier, stable Raman amplification can be performed.

Further, in the semiconductor laser module shown in FIG. 11, since it is necessary to optically couple the optical fiber 203 having the fiber grating 233 and the laser element 202, alignment of optical axis becomes necessary at the time of assembly of the semiconductor laser device, and hence time and labor are required. In this semiconductor laser device 1 according to the first embodiment, however, the alignment of optical axis is not for the resonator but for the optical output, and hence the assembly becomes easy. In the semiconductor laser module shown in FIG. 11, since a mechanical coupling is required in the resonator, there is the possibility that the oscillation characteristic of the laser may change due to vibrations. In the semiconductor laser device 1 in the first embodiment, however, there is no change in the oscillation characteristic of the laser due to mechanical vibrations, and hence stable optical output can be obtained.

According to the first embodiment, since the semiconductor laser device 1 performs wavelength selection by the reflection film 4, it does not require a grating. Therefore, since optical coupling between an optical fiber having the fiber grating and a semiconductor light emission element is not performed in the resonator, the assembly becomes easy, thereby an unstable output due to mechanical vibrations can be avoided, and a low cost semiconductor laser device can be obtained.

(Second Embodiment)

A second embodiment of this invention will now be explained. In the above-described first embodiment, the SiO₂ film and the Si film are alternately and directly formed on the reflection side end surface of the laser element 2 to form the dielectric multilayer film so as to make the reflection film 4 have the wavelength selectivity. However, in this second embodiment, formation of a dielectric multilayer film, which is the reflection film 4, is performed independently of the laser element 2, and the dielectric multilayer film is combined with the laser element 2 side.

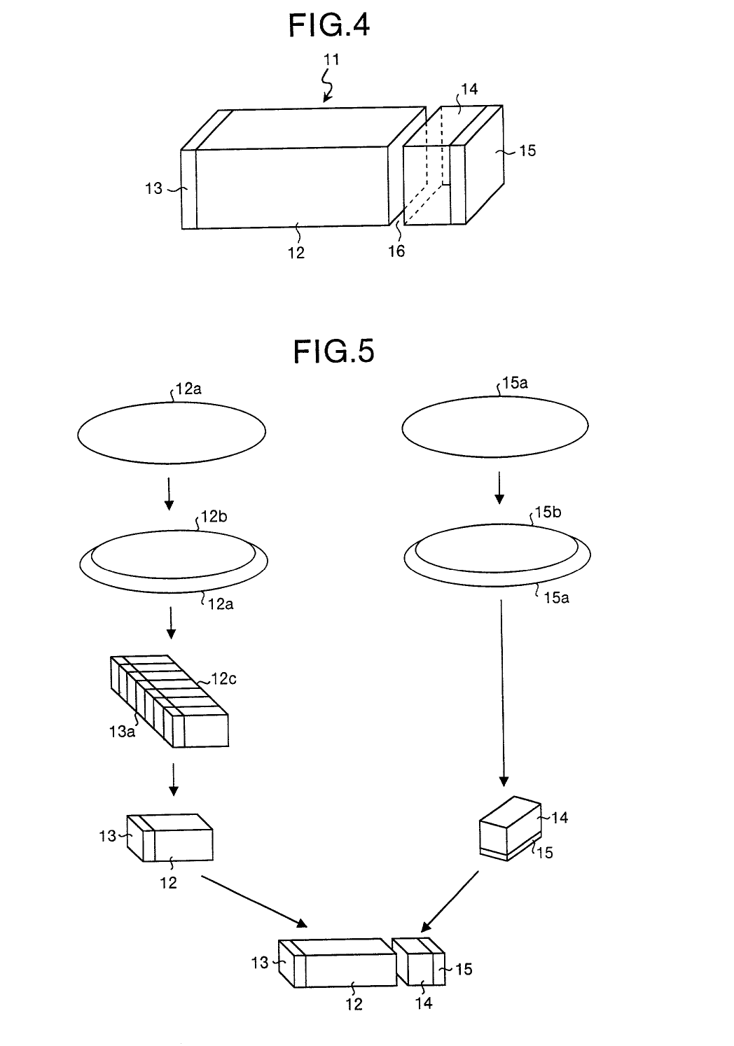

FIG. 4 is a perspective view which shows the schematic structure of a semiconductor laser device, which is a second embodiment of this invention. This semiconductor laser device 11 has a laser element 12, a transmission film 13, a reflection film substrate 15 and a reflection film 14. The laser element 12 has an active layer (not shown) therein, and emits light when a driving current is supplied. The transmission film 13 having a reflectivity of not larger than 5% is formed on one end surface of the laser element 12 in the longitudinal direction. The reflection film 14 is formed on the reflection film substrate 15, and installed via the laser element 12 and a space 16. The transmission film 13 and the reflection film 14 form an optical resonator. Light generated inside the laser element 12 propagates reciprocally in the optical resonator, amplified by induced emission, and is emitted from the transmission film 13 as a laser beam.

The reflection film 14 is a dielectric multilayer film formed on the reflection film substrate 15, by forming an SiO₂ film and an Si film alternately, as in the first embodiment. By forming the SiO₂ film and the Si film alternately, the reflection film 14 has the narrow-band wavelength selection characteristic. The wavelength selection characteristic by this reflection film 14 is similar to the reflection film 4 of the first embodiment, and the light having a wavelength λ₀ of from 1475 nm to 1485 nm is reflected. The laser element 12 and the reflection film 14 are fixed via the space 16, and this space 16 is made as small as possible, to suppress a decrease in output due to optical spreading as mush as possible.

The production method of the semiconductor laser device 11 in the second embodiment will be explained with reference to FIG. 5. First, a multilayer film 12b including an active layer is formed on a semiconductor wafer 12a, by performing processing such as film forming and etching. Thereafter, the semiconductor wafer 12a on which this multilayer film 12b is formed is cleaved, to form a laser bar 12c. A transmission film 13a is formed on the radiation side end surface of the laser bar 12c, and the laser bar 12c is cut into each laser element. On the other hand, an SiO₂ film and an Si film are alternately formed on a semiconductor wafer 15a repeatedly, to thereby form a dielectric multilayer film 15b. It is cleaved into a desired size to form a reflection film 14. Alternatively, the reflection film 14 may be formed by forming the SiO₂ film and the Si film alternately on the semiconductor wafer repeatedly, which has been cleaved into a desired size beforehand.

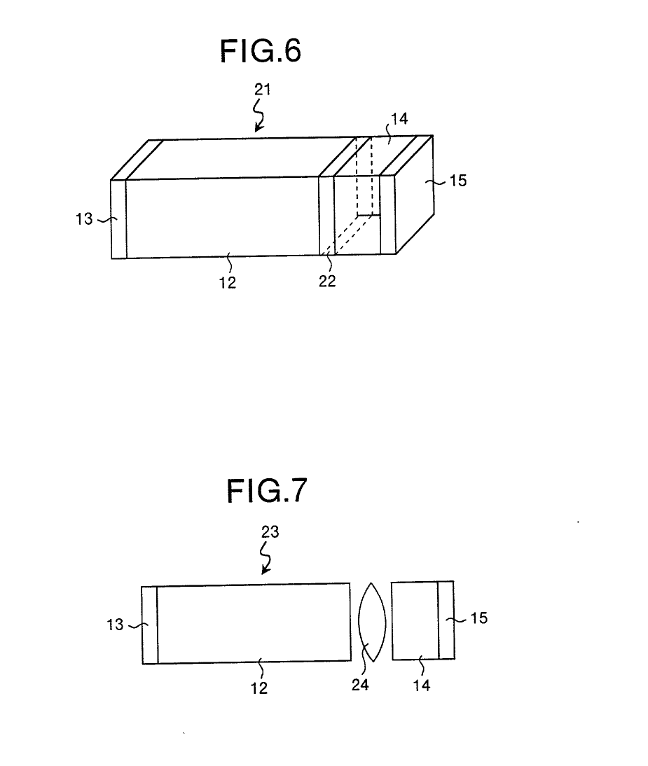

Then, the laser element 12 and the reflection film 14 are fixed with the space 16, to thereby form the semiconductor laser device 11. The laser element 12 and the reflection film 14 may be bonded using a plastic resin or a semiconductor resin which transmits light. FIG. 6 is a perspective view which shows an instance when the laser element 12 and the reflection film 14 are bonded by a permeable resin. In the semiconductor laser device 21, since the laser element 12 and the reflection film 14 are bonded by a light permeable resin 22, the laser element 12 and the reflection film 14 can be easily fixed.

A lens may be provided between the laser element 12 and the reflection film 14. FIG. 7 is a sectional view which shows an instance of a semiconductor laser device when a lens is provided between the laser element 12 and the reflection film 14. A semiconductor laser device 23 has a lens 24 between the laser element 12 and the reflection film 14. Light emitted from the laser element 12 is collected by the lens 24 and is incident onto the reflection film 14. Further, light incident onto the reflection film 14 is reflected by the reflection film 14, and again collected by the lens 24, to enter into the laser element 12. Therefore, an optical spread loss between the laser element 12 and the reflection film 14 can be suppressed.

According to the second embodiment, in the semiconductor laser device 11, the reflection film having wavelength selectivity and the laser element are formed independently, and assembled. Hence, a grating is not required, and the semiconductor device which can be produced easily can be obtained.

Further, the laser element and the reflection film can be easily fixed by bonding the laser element and the reflection film using a light permeable resin.

By providing a lens between laser element and the reflection film, an optical spread loss can be also suppressed.

(Third Embodiment)

A third embodiment of this invention will now be explained. In this third embodiment, the semiconductor laser devices shown in the first and second embodiments are modulated.

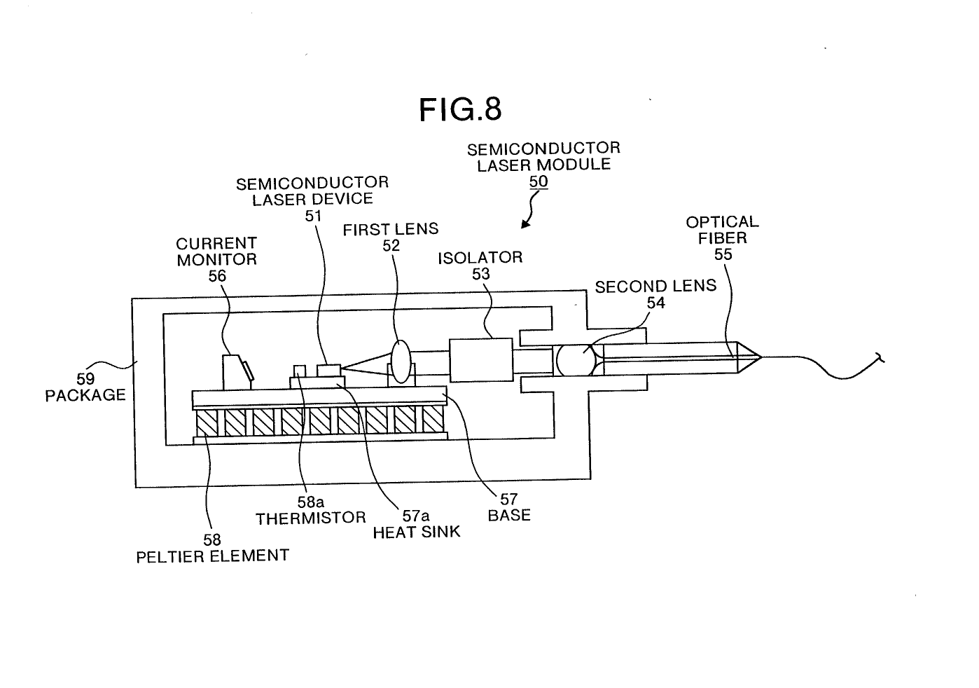

FIG. 8 is a longitudinal sectional view which shows the structure of a semiconductor laser module, which is the third embodiment of this invention. In FIG. 8, this semiconductor laser module 50 has a semiconductor laser device 51 corresponding to the semiconductor laser device shown in the first or second embodiment. As a housing of the semiconductor laser module 50, a Peltier element 58 as a temperature control unit is arranged on the inner bottom surface of a package 59 formed of ceramics or the like. On the Peltier element 58, there is arranged a base 57, and a heat sink 57a is arranged on this base 57. Electric current (not shown) is supplied to the Peltier element 58, and cooling and heating are carried out due to the polarity of the current, but it serves mainly as a cooler in order to prevent a deviation of the oscillation wavelength due to a temperature rise of the semiconductor laser device 51. That is to say, when the laser beam has a longer wavelength than a desired wavelength, the Peltier element 58 controls to a low temperature by cooling, and when the laser beam has a shorter wavelength than the desired wavelength, it controls to a high temperature by heating. This temperature control is performed based on a detection value of a thermistor 58a arranged specifically on the heat sink 57a, and in the vicinity of the semiconductor laser device 51. Generally, a control unit (not shown) controls the Peltier element 58 so as to maintain the temperature of the heat sink 57a constant. The control unit (not shown) also controls the Peltier element 58 so that the temperature of the heat sink 57a decreases with an increase of the driving current of the semiconductor laser device 51. By performing such temperature control, the wavelength stability of the semiconductor laser device 51 can be improved, thereby improving the yield.

On the base 57, there are arranged the heat sink 57a having the semiconductor laser device 51 and the thermistor 58a arranged thereon, a first lens 52 and a current monitor 56. The laser beam emitted from the semiconductor laser device 51 is wave-guided onto an optical fiber 55, through the first lens 52, an isolator 53 and a second lens 54. The second lens 54 is provided on the optical axis of the laser beam and on the package 59, and optically coupled to the optical fiber 55 that is externally connected. The current monitor 56 monitors and detects light leaked from the reflection film side of the semiconductor laser device 51.

In this semiconductor laser module 50, the isolator 53 is interposed between the semiconductor laser device 51 and the optical fiber 55, so that the reflected return light due to other optical parts does not return to the resonator. For this isolator 53, not an in-line type fiber model, but a large isolator can be used, different from the conventional semiconductor laser module using the fiber grating. Hence, insertion loss by the isolator can be made small.

(Fourth Embodiment)

A fourth embodiment of this invention will now be explained. In this fourth embodiment, the semiconductor laser module shown in the above third embodiment is applied to a Raman amplifier.

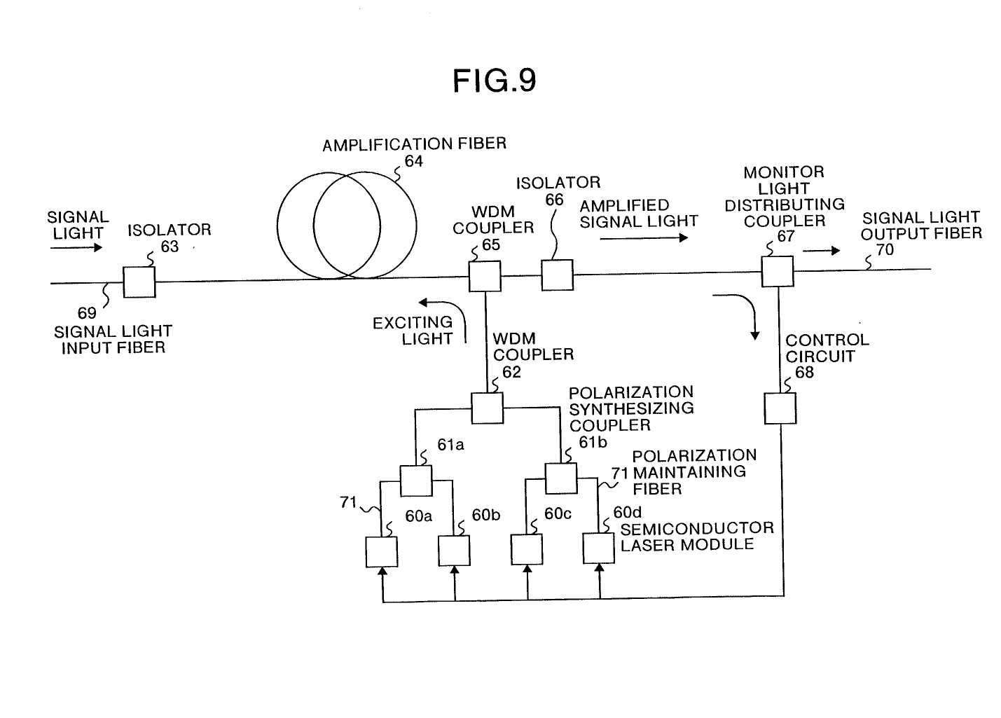

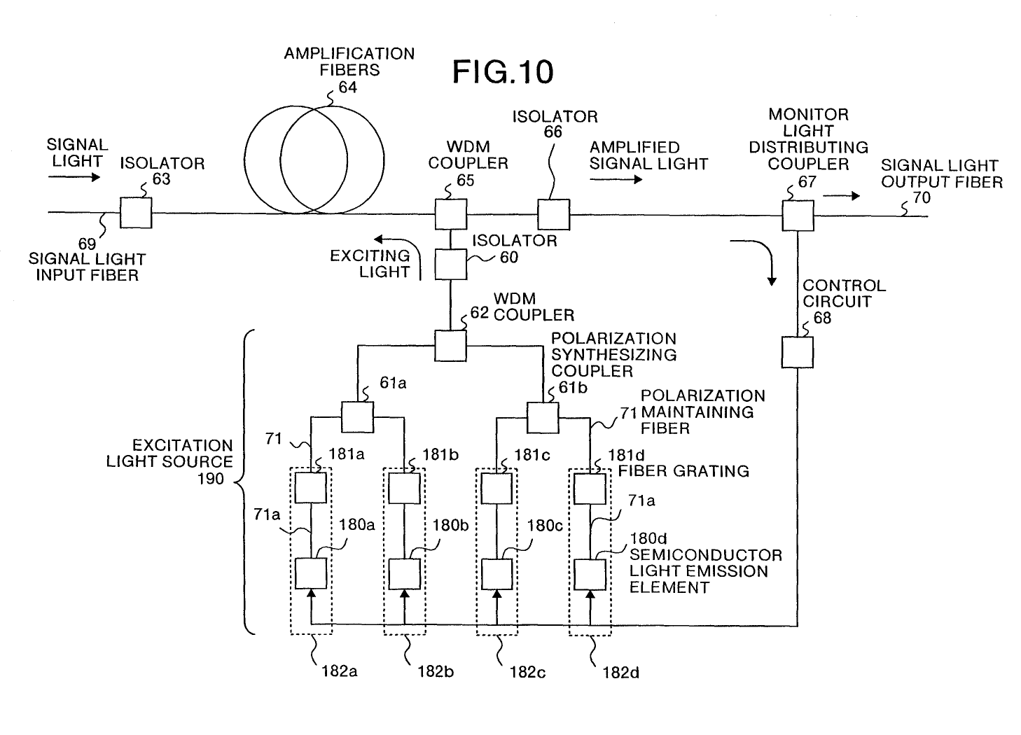

FIG. 9 is a block diagram which shows the structure of the Raman amplifier, which is the fourth embodiment of this invention. This Raman amplifier is used for the WDM communication system. In FIG. 9, this Raman amplifier has such a structure that semiconductor laser modules 60a to 60d having the same structure as the semiconductor laser module shown in the above third embodiment are used, and the semiconductor laser modules 182a to 182d shown in FIG. 10 are replaced with the semiconductor laser modules 60a to 60d.

Each of the semiconductor laser modules 60a and 60b outputs a laser beam having a plurality of oscillation longitudinal modes to a polarization synthesizing coupler 61a through a polarization maintaining fiber 71. Each of the semiconductor laser modules 60c and 60d outputs a laser beam having a plurality of oscillation longitudinal modes to a polarization synthesizing coupler 61b through the polarization maintaining fiber 71. The laser beams oscillated by the semiconductor laser modules 60a and 60b have the same wavelength. The laser beams oscillated by the semiconductor laser modules 60c and 60d have the same wavelength but it is different from the wavelengths of the laser beams oscillated by the semiconductor laser modules 60a and 60b. This is because the Raman amplification has a polarization dependency, so that the laser beam is output by the polarization synthesizing couplers 61a and 61b, with the polarization dependency being eliminated.

The laser beams having a different wavelengths output from each of the polarization synthesizing couplers 61a and 61b are synthesized by a WDM coupler 62, and the synthesized laser beam is output to an amplification fiber 64 as exciting light for Raman amplification through a WDM coupler 65. A signal light to be amplified is input to the amplification fiber 64 to which the exciting light has been input, and is Raman-amplified.

The signal light (amplified signal light) which has been Raman-amplified in the amplification fiber 64 is input to a monitor light distributing coupler 67 through the WDM coupler 65 and an isolator 66. The monitor light distributing coupler 67 outputs a part of the amplified signal light to a control circuit 68, and outputs the remaining amplified signal light to a signal light output fiber 70 as an output laser beam.

The control circuit 68 controls the laser output state, for example, the optical intensity of the semiconductor laser modules 60a to 60d, based on the input part of the amplified signal light and feedback controls so that the gain band of the Raman amplification has a flat characteristic.

In the Raman amplifier shown in this fourth embodiment, for example, a semiconductor laser module 182a, in which the semiconductor light emission element 180a and the fiber grating 181a shown in FIG. 10 are coupled to each other by a polarization maintaining fiber 71a, is not used, but the semiconductor laser module 60a having the semiconductor laser device shown in the first or second embodiment built therein is used. Hence, it is possible to reduce the use of the polarization maintaining fiber 71a. Further, as explained above, since the respective semiconductor laser modules 60a to 60d have a plurality of oscillation longitudinal modes, the length of the polarization maintaining fiber can be reduced. As a result, reduction in size and weight of the Raman amplifier, and cost reduction thereof can be realized.

The operation effects of the first and second embodiments can be given to the Raman amplifier. For example, since relative intensity noise (RIN) can be reduced as compared with a semiconductor laser module using a fiber grating, fluctuations in the Raman gain can be suppressed, and stable Raman amplification can be performed.

Since the semiconductor laser devices in the first and second embodiments have a plurality of oscillation longitudinal modes, an exciting light with high output can be generated without causing induced Brillouin scattering, and hence high Raman gain can be stably obtained.

The Raman amplifier shown in FIG. 9 employs a rear-side excitation method, but as explained above, stable Raman amplification can be performed even in the front-side excitation method or the bi-directional excitation method.

As explained above, according to the present invention, the semiconductor laser device comprises a dielectric multilayer film having the reflection wavelength bandwidth of not larger than 10 nm, on the laser beam reflection side end surface of the laser element having the active layer therein, to reflect light generated in the active layer. Hence, there is the effect that wavelength selection of the laser beam can be performed without using a grating.

According to the present invention, the semiconductor device forms the resonator by combining the laser element provided with a transmission film on the radiation side end surface thereof and a dielectric multilayer film having the reflection wavelength bandwidth of not larger than 10 nm. Hence, there is the effect that a semiconductor laser device which performs wavelength selection of the laser beam without using a grating can be easily produced.

According to the present invention, the laser element and the dielectric multilayer film are arranged close to each other with a predetermined space to thereby form a resonator. Hence, there is the effect that a semiconductor laser device that performs wavelength selection of the laser beam without using a grating can be obtained with a simple construction.

According to the present invention, light excited in the active layer of the laser element reaches the reflection film through the condenser lens, which is reflected by the reflection film, and enters into the laser element through the condenser lens again. Hence, there is the effect that an optical spread loss between the laser element and the dielectric multilayer film can be suppressed.

According to the present invention, since the laser element and the reflection film are bonded by a light permeable resin, there is the effect that the laser element and the dielectric multilayer film can be easily fixed.

According to the present invention, the width of the reflection wavelength band of the dielectric multilayer film is such that the dielectric multilayer film has a reflectivity of not smaller than 90% in the reflection wavelength band, and a reflectivity of not larger than 20% outside the reflection wavelength band. Hence, there is the effect that light in the reflection wavelength band is accurately reflected, and light outside the reflection wavelength band is cut, to thereby enabling accurate wavelength selection.

According to the present invention, the oscillation wavelength is set to be from 1300 nm to 1550 nm, so as to perform Raman amplification of a signal light in the wavelength band which is suitable for the transmission band of the optical fiber. Hence, there is the effect that Raman amplification of a signal light in the wavelength band which is suitable for the transmission band of the optical fiber can be performed.

According to the present invention, by designating the resonator length as not to be smaller than 800 μm, the mode distance between the oscillation longitudinal modes is reduced, so that a plurality of oscillation longitudinal modes are included in the oscillated laser beam. Hence, there is the effect that a semiconductor laser device that suppresses Brillouin scattering and performs laser oscillation of high output can be obtained.

According to the present invention, the laser beam reflection film has a reflectivity of not smaller than 95% in the reflection wavelength range, and the reflectivity outside the reflection wavelength bandwidth is not larger than 10%. Hence, there is the effect that a semiconductor laser device that can take out an excited light efficiently can be obtained.

According to the present invention, a laser beam including a plurality of longitudinal modes is oscillated by combining the width of the reflection wavelength band of the laser beam reflection film and the resonator length, to thereby suppress Brillouin scattering. Hence, there is the effect that a semiconductor laser device that emits a laser beam of high output stably and is suitable as a light source for Raman amplification can be obtained.

According to the present invention, since a semiconductor laser device which does not use a fiber grating is used, a large isolator can be used, different from the in-line type fiber, thereby enabling realization of a semiconductor laser module having a small insertion loss.

According to the present invention, the semiconductor laser device or the semiconductor laser module explained above is used as an excitation light source for broadband Raman amplification, so that the operation effects of each of the semiconductor laser devices or each of the semiconductor laser modules can be exerted. Hence, there is the effect that stable and highly reliable Raman amplification can be performed.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor laser device in which an optical resonator is formed by providing a transmission film having a low reflectivity on a laser beam radiation end surface side of a laser element having an active layer therein, and a reflection film having a high reflectivity on a laser beam reflection end surface side, and
said reflection film is formed by a dielectric multilayer film having a reflection wavelength bandwidth set to be not larger than 10 nm.

2. The semiconductor laser device according to claim 1, wherein said reflection film has a reflectivity in the reflection wavelength bandwidth of not smaller than 90%, and a reflectivity outside the reflection wavelength bandwidth of not larger than 20%.

3. The semiconductor laser device according to claim 1, wherein the oscillation wavelength is from 1300 to 1550 nm.

4. The semiconductor laser device according to claim 1, wherein a resonator length of said optical resonator is not smaller than 800 μm.

5. The semiconductor laser device according to claim 1, wherein said reflection film has a reflectivity in the reflection wavelength bandwidth of not smaller than 95%, and a reflectivity outside the reflection wavelength band width of not larger than 10%.

6. The semiconductor laser device according to claim 1, wherein a laser beam including at least two oscillation longitudinal modes in the oscillation wavelength spectrum is output by setting a combination of oscillation parameters including the resonator length of said optical resonator and the reflection wavelength bandwidth of said reflection film.

7. A semiconductor laser device comprising:
a laser element body provided with a transmission film having a low reflectivity on a laser beam radiation end surface side of a laser element having an active layer therein; and
a reflection film which is physically independent of said laser element body, and is formed by a high-reflectivity dielectric multilayer film having a reflection wavelength bandwidth set to be not larger than 10 nm, to function as a reflection end surface of an optical resonator,
wherein an optical resonator is formed such that the active layer is interposed between said transmission film and said reflection film.

8. The semiconductor laser device according to claim 7, wherein said optical resonator is formed by arranging the end surface which faces the transmission film of said laser element body and said reflection film, so as to come close to each other with predetermined space.

9. The semiconductor laser device according to claim 7, wherein said optical resonator is formed by providing a condenser lens between the end surface which faces the transmission film of said laser element body and said reflection film.

10. The semiconductor laser device according to claim 7, which comprises a bonding member provided between the end surface which faces the transmission film of said laser element body and said reflection film, and formed of a light permeable resin, to thereby form said optical resonator in which said bonding member is inserted.

11. The semiconductor laser device according to claim 7, wherein said reflection film has a reflectivity in the reflection wavelength bandwidth of not smaller than 90%, and a reflectivity outside the reflection wavelength bandwidth of not larger than 20%.

12. The semiconductor laser device according to claim 7, wherein the oscillation wavelength is from 1300 to 1550 nm.

13. The semiconductor laser device according to claim 7, wherein a resonator length of said optical resonator is not smaller than 800 μm.

14. The semiconductor laser device according to claim 7, wherein said reflection film has a reflectivity in the reflection wavelength bandwidth of not smaller than 95%, and a reflectivity outside the reflection wavelength bandwidth of not larger than 10%.

15. The semiconductor laser device according to claim 7, wherein a laser beam including at least two oscillation longitudinal modes in the oscillation wavelength spectrum is output by setting a combination of oscillation parameters including the resonator length of said optical resonator and the reflection wavelength bandwidth of said reflection film.

16. A semiconductor laser module comprising:
a semiconductor laser device in which an optical resonator is formed by providing a transmission film having a low reflectivity on a laser beam radiation end surface side of a laser element having an active layer therein, and a reflection film having a high reflectivity on a laser beam reflection end surface side, and said reflection film is formed by a dielectric multilayer film having a reflection wavelength bandwidth set to be not larger than 10 nm;
an optical fiber which wave-guides the laser beam emitted from said semiconductor laser device to the outside;
an optical coupling lens system which optically couples said semiconductor laser device and said optical fiber;
a temperature control unit which controls the temperature of said semiconductor laser device; and
an isolator arranged in the optical coupling lens system, to control the incidence of a reflected return light from the optical fiber side.

17. A semiconductor laser module comprising:
a semiconductor laser device comprising a laser element body provided with a transmission film having a low reflectivity on a laser beam radiation end surface side of a laser element having an active layer therein, and a reflection film which is physically independent of said laser element body, and is formed by a high-reflectivity dielectric multilayer film having a reflection wavelength bandwidth set to be not larger than 10 nm, to function as a reflection end surface of an optical resonator, wherein an optical resonator is formed such that the active layer is interposed between said transmission film and said reflection film;
an optical fiber which wave-guides the laser beam emitted from said semiconductor laser device to the outside;
an optical coupling lens system which optically couples said semiconductor laser device and said optical fiber;
a temperature control unit which controls the temperature of said semiconductor laser device; and
an isolator arranged in the optical coupling lens system, to control the incidence of a reflected return light from the optical fiber side.

18. A Raman amplifier using, as an excitation light source for broadband Raman amplification, a semiconductor laser device in which an optical resonator is formed by providing a transmission film having a low reflectivity on a laser beam radiation end surface side of a laser element having an active layer therein, and a reflection film having a high reflectivity on a laser beam reflection end surface side, and said reflection film is formed by a dielectric multilayer film having a reflection wavelength bandwidth set to be not larger than 10 nm.

19. A Raman amplifier using, as an excitation light source for broadband Raman amplification, a semiconductor laser device comprising a laser element body provided with a transmission film having a low reflectivity on a laser beam radiation end surface side of a laser element having an active layer therein, and a reflection film which is physically independent of said laser element body, and is formed by a high-reflectivity dielectric multilayer film having a reflection wavelength bandwidth set to be not larger than 10 nm, to function as a reflection end surface of an optical resonator, wherein the optical resonator is formed such that the active layer is interposed between said transmission film and said reflection film.

20. A Raman amplifier using, as an excitation light source for broadband Raman amplification, a semiconductor laser module comprising:
a semiconductor laser device in which an optical resonator is formed by providing a transmission film having a low reflectivity on a laser beam radiation end surface side of a laser element having an active layer therein, and a reflection film having a high reflectivity on a laser beam reflection end surface side, and said reflection film is formed by a dielectric multilayer film having a reflection wavelength bandwidth set to be not larger than 10 nm;
an optical fiber which wave-guides the laser beam emitted from said semiconductor laser device to the outside;
an optical coupling lens system which optically couples said semiconductor laser device and said optical fiber;
a temperature control unit which controls the temperature of said semiconductor laser device; and
an isolator arranged in the optical coupling lens system, to control the incidence of a reflected return light from the optical fiber side.

21. A Raman amplifier using, as an excitation light source for broadband Raman amplification, a semiconductor laser module comprising:
a semiconductor laser device comprising a laser element body provided with a transmission film having a low reflectivity on a laser beam radiation end surface side of a laser element having an active layer therein, and a reflection film which is physically independent of said laser element body, and is formed by a high-reflectivity dielectric multilayer film having a reflection wavelength bandwidth set to be not larger than 10 nm, to function as a reflection end surface of an optical resonator, wherein an optical resonator is formed such that the active layer is interposed between said transmission film and said reflection film;
an optical fiber which wave-guides the laser beam emitted from said semiconductor laser device to the outside;
an optical coupling lens system which optically couples said semiconductor laser device and said optical fiber;
a temperature control unit which controls the temperature of said semiconductor laser device; and
an isolator arranged in the optical coupling lens system, to control the incidence of a reflected return light from the optical fiber side.
